(19) United States
(12) Patent Application Publication
(10) Pub. No.: US 2026/0133153 A1
(43) Pub. Date: May 14, 2026

(54) INSERTION LOSS SENSOR FOR TESTING IMMERSION COOLING LIQUIDS

(71) Applicant: Seagate Technology LLC, Fremont, CA (US)

(72) Inventors: Barish Chakravarty, Shugart (SG); Xiaolei Liao, Shugart (SG); Swee Chuan Gan, Shugart (SG); Xiong Liu, Shugart (SG); Lihong Zhang, Shugart (SG)

(21) Appl. No.: 18/943,598

(22) Filed: Nov. 11, 2024

(51) Int. Cl. G01N 27/22; H05K 1/02; H05K 7/20

(52) U.S. Cl. CPC G01N 27/221; H05K 1/0242; H05K 7/20236; H05K 7/20281; H05K 2201/10189

(57) ABSTRACT

Described are electrical sensors for measuring the insertion loss spectrum of fluids such as immersion cooling liquids. Such insertion loss sensors have a roughly U-shaped detection trace that is devoid of sharp corners to thereby allow for a sufficiently long trace in a relatively compact design and in which the electrical connectors can be disposed on the same end of the printed circuit board on which the detection trace is formed. Such designs may provide for the use of smaller volumes of cooling liquid contained in smaller containers, as well as for avoiding the immersion of the electrical connectors into the cooling liquid that is being tested.

### TECHNICAL FIELD

This disclosure relates to insertion loss testing of immersion cooling fluids.

### SUMMARY

In accordance with various aspects, the present disclosure describes insertion loss sensors for measuring insertion loss in a fluid. Such insertion loss sensors include a printed circuit board defining a first edge, along with a U-shaped detection trace configured to sense insertion loss, the U-shaped detection trace extending along a U-shaped path from a first end to a second end, the first end and the second end both terminating at or near the first edge of the printed circuit board. The U-shaped detection trace is devoid of any sharp corners along the U-shaped path. The sensors also include first and second connectors disposed on the first edge of the printed circuit board, each electrically connected to a respective end of the U-shaped detection trace. The sensor may be a single trace insertion loss sensor or a differential insertion loss sensor.

In certain aspects, the trace length and PCB material are tuned for expected power losses in a frequency band of about 6 GHz or greater that are less than 1 dB in air. In certain aspects, evenly-spaced ground via holes may be disposed along an inner and outer perimeter of the U-shaped detection trace, thus providing an insertion loss sensor bandwidth of about 10 GHz or greater. Ground via holes may also be disposed along a perimeter of the printed circuit board.

In certain aspects, the printed circuit board includes at a top surface thereof an insulating layer, a conductive signal layer disposed on the insulating layer, and a conductive corrosion protection layer disposed on the conductive signal layer. As such, the detection trace is defined by grooves extending through the conductive corrosion protection layer and the conductive signal layer to thereby expose the insulating layer. In certain aspects, the conductive signal layer is a layer of copper having a thickness of about 1.8 mils, and the conductive corrosion protection layer is a layer of gold having a thickness of about 0.005 mils. Moreover, the insulating layer may be a layer of RO4003C having a thickness of about 8 mils. In certain aspects, the printed circuit boards includes a gold corrosion protection layer on a bottom surface thereof.

In accordance with various aspects, the present disclosure describes immersion cooling systems that include an immersion cooling tank holding an immersion cooling liquid and a plurality of electronic devices immersed in the immersion cooling liquid, and the describe insertion loss sensor mounted in the immersion cooling tank such that the U-shaped detection trace is fully immersed in the immersion cooling liquid. The sensor can be mounted so that the connectors remain outside of the cooling liquid. This includes providing sealed feedthroughs in the immersion cooling tank.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic top view of an insertion loss sensor in accordance with aspects of the present disclosure.

FIG. 2 is a schematic cross-sectional view of a circuit board of an insertion loss sensor in accordance with aspects of the present disclosure.

FIG. 3 is a schematic view of the submersion into a test liquid of an insertion loss sensor in accordance with aspects of the present disclosure.

FIG. 4 compares different ways of providing a curved U-shape trace for an insertion loss sensor in accordance with aspects of the present disclosure.

FIG. 5 is a schematic top view of a differential insertion loss sensor in accordance with aspects of the present disclosure.

FIG. 6 is a schematic view of an immersion cooling tank.

### DETAILED DESCRIPTION

The present disclosure relates to electrical sensors for measuring the insertion loss spectrum of fluids such as immersion cooling liquids. In particular, insertion loss sensors in accordance with the present disclosure may have a roughly U-shaped detection trace that is devoid of sharp corners to thereby allow for a sufficiently long trace in a relatively compact design and in which the electrical connectors can be disposed on the same end. Such designs may provide for the use of smaller volumes of cooling liquid contained in smaller containers, as well as for avoiding the immersion of the electrical connectors into the cooling liquid that is being tested. Such designs are suitable for testing in situ in immersion cooling tanks as well as in external containers, such as on the lab bench. In certain aspects, the insertion loss sensors of the present disclosure may provide for enhanced measurement sensitivity and accuracy while suppressing return losses and signal mismatch.

Insertion loss is the loss of signal due to transmission in a medium or along a transmission line. For immersion cooling liquids, it has been found that measuring insertion loss in the liquid may be used to suitably determine changes in the dielectric constant of the cooling liquid, which may be caused by chemical reactions, oxidation, dissolution of contaminants, and breakdown of components such as circuit boards, connectors, wire insulation, and so forth. The dielectric properties of an immersion cooling liquid that is being used to cool electronic devices (such as GPUs or other compute devices, as well as HDDs or other data storage devices) can directly impact the signal integrity and reliability of those electronic devices while immersed in the cooling liquid. Such an impact may be escalated in the high frequency range (for example, greater than about 6 GHz).

Insertion loss measurements in an immersion cooling liquid have been conventionally performed using a printed circuit board (PCB) embedded with a straight, linear conductive trace. In general, longer traces provide for increased measurement sensitivity, but can also lead to more signal reflections, phase distortion, and return loss. During measurements, the PCB is immersed in the liquid to be tested, and therefore larger containers and correspondingly larger volumes of liquid are needed to accommodate sensors having longer traces. Also, the configuration of linear trace insertion loss sensors generally requires submersion of the electrical connectors (often precision coaxial RF connectors such as SMA connectors), which can harm the connectors, deteriorate the cables, and affect measurements.

Such concerns may be addressed using insertion loss sensors in accordance with various aspects of the present disclosure, which insertion loss sensors include U-shaped traces. The curved portions of the U-shaped traces may be designed to avoid sharp or abrupt corners that can lead to signal reflections and thereby harm signal accuracy and sensitivity. Traces may be considered to be devoid of sharp corners when the trace may be described by a smooth function, or in other words a continuous function whose derivative is also a continuous function. In certain aspects, traces may be formed that are devoid of sharp corners by joining curved segments to straight segments where the straight segments follow the tangent line of the curved segment at the point where the segments are joined.

The present disclosure provides insertion loss sensors that are sensitive enough to measure the insertion loss of immersion cooling liquids, and even sensitive enough to differentiate from among different types of immersion cooling liquids, such as engineered cooling fluids available under the trade designations Novec 650 and Novec 7000, hydrocarbon based cooling liquids such as those available under the trade designation SmartCoolant, and so forth. Insertion loss sensors may be designed to have a trace length and PCB material tuned for power losses expected for a given frequency band of interest so that the insertion loss is less than 1 dB in air.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements.

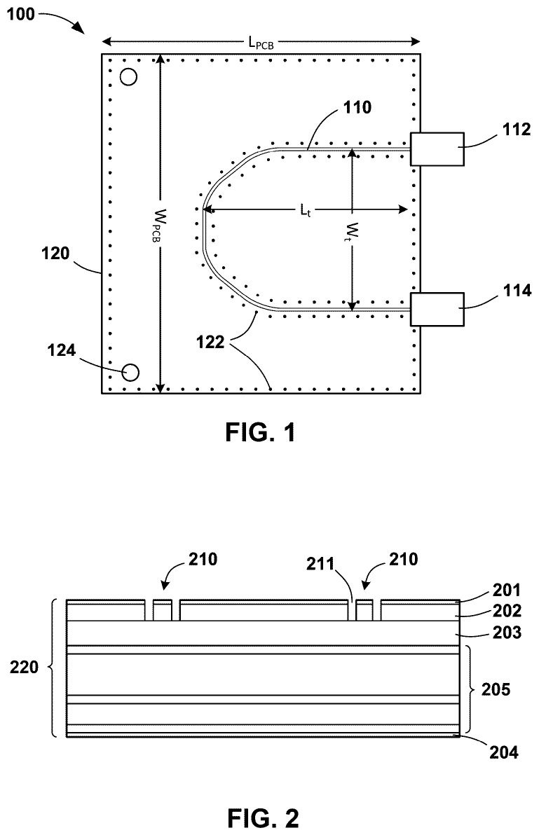

FIG. 1 schematically depicts a top view of an example insertion loss sensor 100 in accordance with various aspects of the present disclosure. Insertion loss sensor 100 includes a U-shaped trace 110 embedded in a low-loss, high-frequency PCB 120. Electrical connection can be made to the trace 110 by edge connectors 112 and 114, which may be solderless PCB edge launch connectors. The U-shaped trace 100 may be constructed to have four 45° arcs that form an overall 180° bend in the trace 100. The 45° arcs may be joined by generally straight segments. This results in an overall U-shaped trace 100 without sharp bends or corners, and with an overall length that is sufficient to achieve a desired sensitivity for the sensor 100. Because of the U-shaped design, the trace can be kept within a rectangular envelope of length Lt and width Wt. This allows the overall size of the sensor 100 to be reduced compared to a linear sensor having a straight trace of the same length. Moreover, the U-shaped construction of trace 110 allows both connectors 112 and 114 to be situated on the same edge of PCB 120 so that the trace 110 can be submerged in the test liquid without submerging the connectors 112 and 114 or any connected wires or devices. The U-shape of the trace 110 may be designed to avoids sharp or sudden bends at the transitions between straight and curved segments of the trace 110, thereby reducing any return losses or impedance mismatch, and thus enhancing signal sensitivity and accuracy. For example, a straight segment may follow a tangent line of the curved segment at the point at which the straight segment meets the curved segment.

PCB 120 may include mounting holes such as hole 124 to facilitate mounting of the insertion loss sensor 100 in an immersion cooling tank or test container. PCB 120 may also include ground via holes 122 evenly distributed around the perimeter of the PCB 120 as well as along the inside and outside edges of trace 110, as indicated. Via holes 122 may be used to suppress high order modes, thereby increasing the sensor bandwidth. The smaller the spacing between the ground via holes 122, the higher the bandwidth. For most immersion cooling liquid testing applications, a bandwidth of 10 GHz is sufficient, which may be accomplished by using a spacing between via holes 122 along a line of via holes of about 30 mils (0.76 mm) to about 60 mils (1.52 mm). The ground via holes 122 extend through the top conductive layer or layers to the first underlying insulating layer of the PCB. The ground via holes may have a diameter of about 5 mils (0.13 mm) to 10 mils (0.25 mm). In certain configurations, a line of ground via holes 122 may be positioned about 10 mils (0.25 mm) to 30 mils (0.76 mm) away from the trace 110, as well as from the edges of the PCB 120.

In the configuration of insertion loss sensor 100, a U-shaped trace 110 having an overall length of about 1.65 inches (4.2 cm) may be accommodated on a PCB 120 having a length L_{PCB} of about 0.9 inches to 1.2 inches (about 2.29 cm to 3.05 cm) and a width W_{PCB} of about 1.2 inches to 1.4 inches (about 3.05 cm to 3.56 cm). The PCB 120 may be of any suitable PCB laminate construction, and may include additional layers or coatings as needed.

FIG. 2 shows a schematic cross-sectional view of a PCB arrangement 220 that may be useful in constructing insertion loss sensors in accordance with aspects of the present disclosure. In many instances, it may be convenient to build an insertion loss sensor from an existing PCB. In such a case, often the configuration of the interior, or “core,” layers of the PCB will not matter for the functionality of the insertion loss sensor. For example, as shown in FIG. 2, PCB 220 may include “core” layers 205 composed of thick dielectric laminate layers of materials commonly used in PCBs such as RO4003C (available from Rogers Corporation) alternated with thin copper cladding layers. PCBs constructed from RO4003C may be used due to the relatively low dielectric constant (3.5) of RO4003C as compared to other PCB insulating layers. The bottom of PCB 220 may be coated with a thin layer of gold (for example, 0.005 mils thick, or about 0.13 microns) to protect against corrosion. The bottom layer 204 does not affect the functioning of the insertion loss sensor per se. On top of the core layers 205 may be an insulating layer 203 such as an 8 mil (0.2 mm) thick layer of RO4003C, a copper signal layer 202 that is about 1.8 mils (0.046 mm) thick, and a gold corrosion protection layer 201 that is about 0.005 mils (0.13 microns) thick. These upper layers 203, 202, and 201 represent the functioning layers of the insertion loss sensor. An exemplary overall layer construction is provided in Table 1.

TABLE 1

| | | Thickness |
|---|---|---|
| Layer | Material | (mils) |
| Top Protective | Gold | 0.005 |
| Signal | Copper | 1.8 |
| Insulating | RO4003C | 8.0 |
| Core | Copper | 0.4 |
| Core | RO4003C | 43.0 |
| Core | Copper | 0.4 |
| Core | RO4003C | 8.0 |
| Core | Copper | 0.4 |
| Bottom Protective | Gold | 0.005 |
| TOTAL | PCB | 62 |

As indicated in FIG. 2, signal trace 210 is made by forming grooves 211 on either side of the trace 210 and extending through the gold protective layer 201 and the copper signal layer 202 to the insulating layer 203. Groove 211 can be made by any suitable PCB patterning technique. The width of the trace 210 between adjacent grooves 211 may be about 10 mils (0.25 mm) to 15 mils (0.38 mm), with the grooves 211 having widths of about 5 mils (0.13 mm) to 8 mils (0.20 mm). The width and depth of the traces 210 and grooves 211 may be tuned to achieve a desired impedance. In the case of a desired impedance of 50 Ohms, and given the PCB construction set forth in Table 1, the width of the traces 210 between adjacent grooves is about 13.5 mils (0.34 mm) and the width of the grooves is about 5.65 mils (0.14 mm).

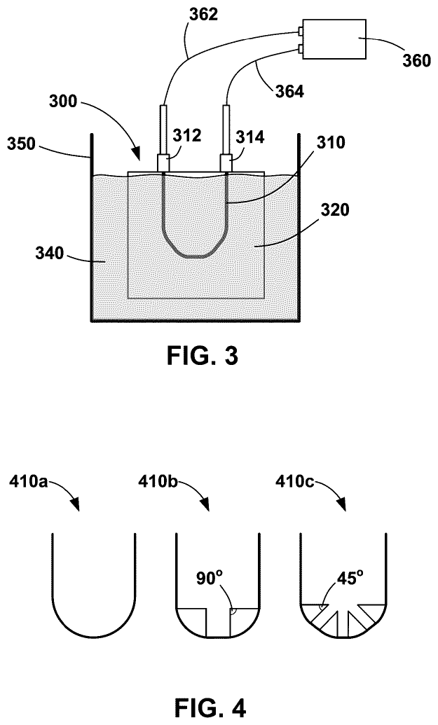

FIG. 3 schematically shows an example of a bench-type test arrangement for measuring insertion loss in a cooling liquid 340 using an insertion loss sensor 300 in accordance with aspects of the present disclosure. Cooling liquid 340 to be tested may be transferred into a container 350. The container may be sized to limit the volume of liquid 340 needed for testing. Insertion loss sensor 300 is made up of a U-shaped detection trace 310 formed on a PCB 320, such as has been previously described herein. The sensor 300 may be submerged in the liquid 340 enough to substantially cover the trace 310, thereby making use of the full length of the trace 310. Because the trace 310 is U-shaped, connectors 312 and 314 may be disposed on the same edge of the PCB 320 of the sensor 300. As such, this configuration allows the connectors 312 and 314 from being submerged in the liquid 340. Signal wires 362 and 364 may be used to connect the sensor 300 to detection electronics 360. Detection electronics 360 may include a signal generator and a power meter to measure insertion loss at a specific frequency. The insertion loss sensor 300 may be constructed for sensitivity within a frequency band of interest (for example, about 6 GHz and greater), and thus a frequency within that band may be used to measure insertion loss.

FIG. 4 illustrates design principles for avoiding sharp bends in U-shaped traces of insertion loss sensors in accordance with the present disclosure. Avoiding sharp corners or bends and minimizing the total curvature of the traces may reduce reflection losses of signal, thereby enhancing detection sensitivity. The curved portion of trace 410a is a continuous semi-circle. Trace 410b includes two quarter circles having arcs that span 90 degrees, with the quarter circles joined by straight segments. Trace 410c includes four eighth circles each having arcs that span 45 degrees, with each of the arcs joined by short, straight segments. Each of these designs 410a, 410b, and 410c can effectively minimize the total curvature and provide for an overall U-shape without introducing sharp corners in the transitions between different segments or portions of the traces. U-shaped traces can provide for a 30% reduction in the overall size of the sensor compared to conventional straight insertion loss sensors, thus facilitating a smaller footprint for the sensor while accommodating various PCB thicknesses and allowing for connectors to be disposed on the same edge.

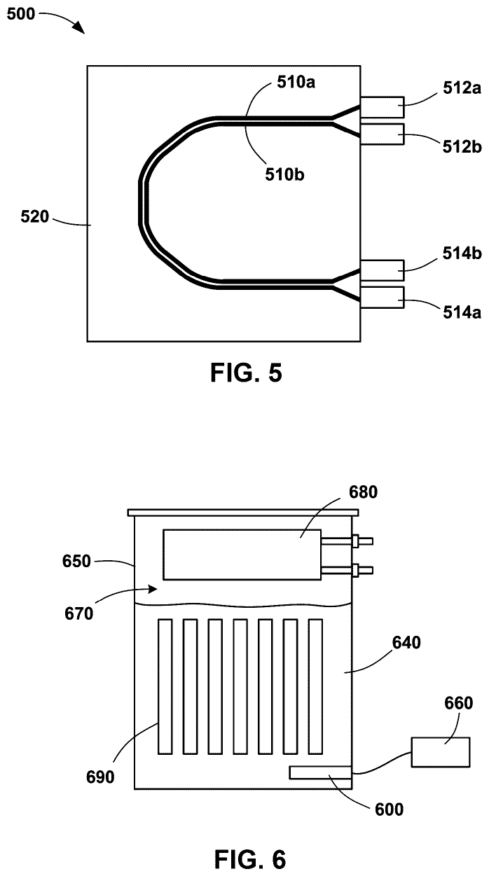

FIG. 5 schematically shows a possible trace configuration for a differential insertion loss sensor 500 in accordance with certain aspects of the present disclosure. A differential insertion loss sensor makes use of a symmetric pair of traces that are closely spaced. As such, the differential insertion loss sensor 500 includes two roughly symmetric U-shaped traces 510a and 510b. However, due to the U-shape, the inner trace 510b will be slightly shorter than the outer trace 510a unless adjustments are made, for example by slightly lengthening trace 510b at its end points to thereby match the overall length of trace 510a. The effective length of the pair of traces for measurement purposes is the length over which the two traces are in close proximity. Typically, each separate trace 510a and 510b has its own pair of connectors, namely connectors 512a and 514a for trace 510a, and connectors 512b and 514b for trace 510b.

FIG. 6 schematically shows an immersion cooling environment in which a cooling tank 650 contains a plurality of electronic devices 690 immersed in a cooling liquid 640. While single-phase and two-phase immersion cooling tanks exist, without loss of generality FIG. 6 depicts a two-phase immersion cooling tank in which a condenser coil 680 resides in a space 670 above the fluid 640 so that when the cooling fluid evaporates it condenses on the coil 680 and drips back into the liquid. The cooling fluid 640 can be tested for insertion loss by removing some of the fluid 640 and placing it into a test apparatus such as shown in FIG. 3. Alternatively, or in addition, the immersion cooling tank 650 may be configured to allow for the mounting of an insertion loss sensor 600 in a location of the tank 650 where the detection trace of the sensor 600 is submerged. For example, the sensor 600 could be located at or near the bottom of the tank 650 (as shown), at or near a side of the tank 650, or closer to the top of the fluid level in the tank 650. Generally, it is preferred that the connectors of sensor 600 not be submerged. In such a case, the sensor 600 may be mounted on the side of tank 650 near the fill level of fluid 640, or the sensor 600 may be mounted anywhere (such as near the bottom of tank 650, as depicted) with the connectors being provided as electrical feedthroughs designed into the tank and sealed against leakage of the cooling liquid. Insertion loss detection electronics 660 may then be connected to the sensor 600 for in situ measurements.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (for example, all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

All scientific and technical terms used herein have meanings commonly used in the art unless otherwise specified. The definitions provided herein are to facilitate understanding of certain terms used frequently herein and are not meant to limit the scope of the present disclosure.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” and so forth, means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. An insertion loss sensor for measuring insertion loss in a fluid, the insertion loss sensor comprising:
a printed circuit board defining a first edge;
a U-shaped detection trace configured to sense insertion loss, the U-shaped detection trace extending along a U-shaped path from a first end to a second end, the first end and the second end both terminating at or near the first edge of the printed circuit board, the U-shaped detection trace being devoid of any sharp corners along the U-shaped path;
a first connector disposed on the straight edge of the printed circuit board and electrically connected to the first end of the U-shaped detection trace; and
a second connector disposed on the straight edge of the printed circuit board and electrically connected to the second end of the U-shaped detection trace.

2. The insertion loss sensor of claim 1 having a U-shaped detection trace length and a printed circuit board material configured for expected power losses in a frequency band of about 6 GHz or greater that are less than 1 dB in air.

3. The insertion loss sensor of claim 1, further comprising a first series of evenly-spaced ground via holes disposed along an outer perimeter of the U-shaped detection trace, and a second series of evenly-spaced ground via holes disposed along an inner perimeter of the U-shaped detection trace.

4. The insertion loss sensor of claim 3, wherein the first series of evenly-spaced ground via holes and the second series of evenly-spaced ground via holes have spacings and hole diameters selected to provide an insertion loss sensor bandwidth of about 10 GHz or greater.

5. The insertion loss sensor of claim 3, further comprising a third series of evenly-spaced ground via holes disposed along a perimeter of the printed circuit board.

6. The insertion loss sensor of claim 1, wherein the printed circuit board includes at a top surface thereof an insulating layer, a conductive signal layer disposed on the insulating layer, and a conductive corrosion protection layer disposed on the conductive signal layer.

7. The insertion loss sensor of claim 6, wherein the detection trace is defined by grooves extending through the conductive corrosion protection layer and the conductive signal layer to thereby expose the insulating layer.

8. The insertion loss sensor of claim 7, wherein the conductive signal layer comprises a layer of copper having a thickness of about 1.8 mils, and the conductive corrosion protection layer comprises a layer of gold having a thickness of about 0.005 mils.

9. The insertion loss sensor of claim 8, wherein the insulating layer comprises a layer of RO4003C having a thickness of about 8 mils.

10. The insertion loss sensor of claim 9, further comprising a first series of evenly-spaced ground via holes disposed along an outer perimeter of the U-shaped detection trace, and a second series of evenly-spaced ground via holes disposed along an inner perimeter of the U-shaped detection trace, wherein each of the ground via holes extends through the conductive corrosion protection layer and the conductive signal layer to the insulating layer.

11. The insertion loss sensor of claim 10, wherein the first and second series of evenly-spaced ground via holes each have a hole-to-hole spacing of about 30 mils to about 60 mils.

12. The insertion loss sensor of claim 10, wherein the first and second series of evenly-spaced ground via holes are each spaced apart from the U-shaped detection trace by about 10 mils to about 30 mils.

13. The insertion loss sensor of claim 10, wherein the ground via holes of the first and second series of evenly-spaced ground via holes each have a diameter of about 5 mils to about 10 mils.

14. The insertion loss sensor of claim 6, wherein the printed circuit boards includes a gold corrosion protection layer on a bottom surface thereof.

15. The insertion loss sensor of claim 1, wherein the printed circuit board has a length and a width that are both less than an overall length of the U-shaped detection trace.

16. The insertion loss sensor of claim 15, wherein the overall length of the U-shaped detection trace is about 1.65 inches.

17. The insertion loss sensor of claim 1, wherein the insertion loss sensor is a differential insertion loss sensor.

18. An immersion cooling system comprising:
an immersion cooling tank holding an immersion cooling liquid and a plurality of electronic devices immersed in the immersion cooling liquid; and
the insertion loss sensor of claim 1 mounted in the immersion cooling tank such that the U-shaped detection trace is fully immersed in the immersion cooling liquid.

19. The immersion cooling system of claim 18, wherein the first connector and the second connector remain out of the cooling liquid.

20. The immersion cooling system of claim 18, wherein the immersion cooling tank includes sealed feedthroughs for electrical connections to the printed circuit board via the first connector and the second connector.

21. The immersion cooling system of claim 18, further comprising detection electronics electrically coupled to the first connector and the second connector, and configured to provide an insertion loss measurement.
